(19) United States
(12) Patent Application Publication
(10) Pub. No.: US 2025/0031459 A1
(43) Pub. Date: Jan. 23, 2025

(54) ELECTRONIC DEVICE

(71) Applicant: InnoLux Corporation, Miao-Li County (TW)

(72) Inventors: Han-Tsung SU, Miao-Li County (TW); Tsan-Chu LU, Miao-Li County (TW); Sheng-Hui CHEN, Miao-Li County (TW); Hong-Kang CHANG, Miao-Li County (TW)

(21) Appl. No.: 18/745,148

(22) Filed: Jun. 17, 2024

Related U.S. Application Data
(60) Provisional application No. 63/527,266, filed on Jul. 17, 2023.

(30) Foreign Application Priority Data
Apr. 1, 2024 (CN) 202410385968.4

(51) Int. Cl. H01L 27/02

(52) U.S. Cl. CPC H01L 27/0292; H01L 27/0255; H01L 27/0266

(57) ABSTRACT

An electronic device is provided, which comprises: a substrate comprising an active region and a peripheral region; a common conductive line disposed corresponding to the peripheral region of the substrate; and a scan line disposed on the substrate, wherein the scan line is electrically connected to a first static discharge conductive line through a first electrostatic protection circuit in the peripheral region, wherein the common conductive line is electrically separated from the first static discharge conductive line; wherein in a top view of the substrate, there is a first distance between the common conductive line and the first static discharge conductive line, and the first distance is greater than or equal to 1.5 μm and less than or equal to 12 mm.

### CROSS-REFERENCE TO RELATED APPLICATIONS

This application claims the benefits of the Chinese Patent Application Serial Number 202410385968.4, filed on Apr. 1, 2024, the subject matter of which is incorporated herein by reference.

This application claims the benefit of filing date of U.S. Provisional Application Ser. No. 63/527,266, filed Jul. 17, 2023 under 35 USC § 119(e)(1).

### BACKGROUND

### Field

The present disclosure provides an electronic device. More specifically, the present disclosure provides an electronic device with a static discharge conductive line.

### Description of Related Art

As technology advances, electronic device technology has gradually matured. However, electronic devices inevitably generate electrostatic charge accumulation during the preparation process. If the electrostatic charge cannot be discharged in time, electrostatic discharge will occur when the accumulated electrostatic charge reaches a certain amount, which may easily cause damage to the components in the electronic device and cause the electronic device to deteriorate. In addition, in the process of discharging static charges, there may also be shortcomings such as signal interference that affects electronic quality.

Therefore, it is desirable to provide an electronic device to improve the above shortcomings.

### SUMMARY

The present disclosure provides an electronic device, which comprises: a substrate comprising an active region and a peripheral region; a common conductive line disposed corresponding to the peripheral region of the substrate; and a scan line disposed on the substrate, wherein the scan line is electrically connected to a first static discharge conductive line through a first electrostatic protection circuit in the peripheral region, wherein the common conductive line is electrically separated from the first static discharge conductive line; wherein in a top view of the substrate, there is a first distance between the common conductive line and the first static discharge conductive line, and the first distance is greater than or equal to 1.5 μm and less than or equal to 12 mm.

Other novel features of the disclosure will become more apparent from the following detailed description when taken in conjunction with the accompanying drawings.

### BRIEF DESCRIPTION OF DRAWINGS

FIG. 1 is a schematic top view of an electronic device according to one embodiment of the present disclosure.

FIG. 2 and FIG. 3 are partial enlarged views of FIG. 1 respectively.

FIG. 4 is a schematic top view of an electronic device according to one embodiment of the present disclosure.

FIG. 5 and FIG. 6 are partial enlarged views of FIG. 4 respectively.

FIG. 7A and FIG. 7B are respectively schematic diagrams of an electrostatic protection circuit according to one embodiment of the present disclosure.

### DETAILED DESCRIPTION

The following is specific embodiments to illustrate the implementation of the present disclosure. Those who are familiar with this technique can easily understand the other advantages and effects of the present disclosure from the content disclosed in the present specification. The present disclosure can also be implemented or applied by other different specific embodiments, and various details in the present specification can also be modified and changed according to different viewpoints and applications without departing from the spirit of the present disclosure.

It should be noted that, in the present specification, when a component is described to have an element, it means that the component may have one or more of the elements, and it does not mean that the component has only one of the element, except otherwise specified. Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names. In the following description and claims, words such as “comprising”, “including”, “containing”, and “having” are open-ended words, so they should be interpreted as meaning “containing but not limited to . . . ”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

The terms, such as “about”, “equal to”, “equal” or “same”, “substantially”, or “approximately”, are generally interpreted as within 10%, 5%, 3%, 2%, 1%, or 0.5% of a given value or range. The quantity given here is an approximate quantity, that is, without specifying “about”, “approximately”, “substantially” and “approximately”, “about”, “approximately”, “substantially” and “approximately” can still be implied. Furthermore, when a value is “in a range from a first value to a second value” or “in a range between a first value and a second value”, the value can be the first value, the second value, or another value between the first value and the second value.

In the present specification, except otherwise specified, the terms (including technical and scientific terms) used herein have the meanings generally known by a person skilled in the art. It should be noted that, except otherwise specified, in the embodiments of the present disclosure, these terms (for example, the terms defined in the generally used dictionary) should have the meanings identical to those known in the art, the background of the present disclosure or the context of the present specification, and should not be read by an ideal or over-formal way.

In addition, relative terms such as “below” or “under” and “on”, “above” or “over” may be used in the embodiments to describe the relative relationship between one element and another element in the drawings. It will be understood that if the device in the drawing was turned upside down, elements described on the “lower” side would then become elements described on the “upper” side. When a unit (for example, a layer or a region) is referred to as being “on” another unit, it can be directly on the another unit or there may be other units therebetween. Furthermore, when a unit is said to be “directly on another unit”, there is no unit therebetween. Moreover, when a unit is said to be “on another unit”, the two have a top-down relationship in a top view, and the unit can be disposed above or below the another unit, and the top-bottom relationship depends on the orientation of the device.

In the present disclosure, the distance and the width may be measured using an optical microscope or using cross-sectional images in an electron microscope, but the present disclosure is not limited thereto. In addition, any two values or directions used for comparison may have certain errors. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°.

It should be noted that the technical solutions provided by different embodiments hereinafter may be replaced, combined or used in combination, so as to constitute another embodiment without violating the spirit of the present disclosure.

The electronic device of the present disclosure may include, for example, a display device, a sensing device, an antenna device, a touch device, a tiled device or other suitable electronic devices, but the present disclosure is not limited thereto. The display device of the present disclosure may be a non-self-luminous display device or a self-luminous display device, such as a liquid crystal display, a cholesteric liquid crystal display, an electro-phoretic display, an organic light emitting diode display or a light emitting diode display, but the present disclosure is not limited thereto. The display device may include a light emitting diode, a light conversion layer, other suitable materials or a combination thereof, but the present disclosure is not limited thereto. The light emitting diode may comprise, for example, an organic light emitting diode (OLED), a mini LED, a micro LED or a quantum dot LED (which may include QLED or QDLED), but the present disclosure is not limited thereto. The light conversion layer may include wavelength conversion materials and/or filter materials. The light conversion layer may include, for example, fluorescence, phosphors, quantum dots (QDs), other suitable materials or a combination thereof, but the present disclosure is not limited thereto. The sensing device may include, for example, a biosensor, a touch sensor, a fingerprint sensor, other suitable sensors, or a combination of the above types of sensors. The antenna device may be, for example, a liquid crystal antenna or other types of antennas, but the present disclosure is not limited thereto. The tiled device may include, for example, a tiled display device or a tiled antenna device, but the present disclosure is not limited thereto. The electronic device may include electronic components, and the electronic components may include passive components, active components, or a combination of the above, such as capacitors, resistors, inductors, varactor diodes, variable capacitors, filters, diodes, transistors, sensors, microelectromechanical system components (MEMS), chips, etc., but the present disclosure is not limited thereto. It should be noted that the electronic device of the present disclosure can be various combinations of the above devices, but is not limited thereto.

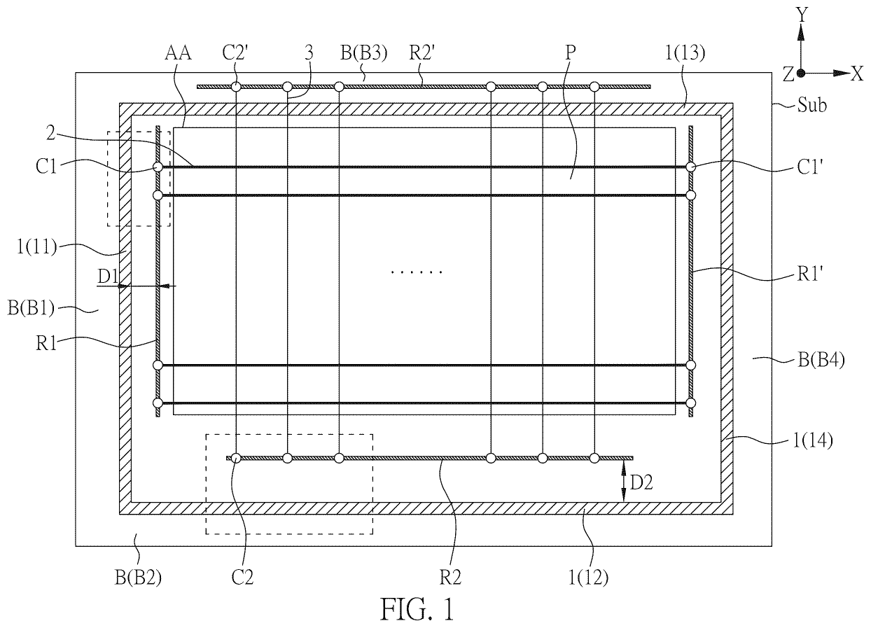

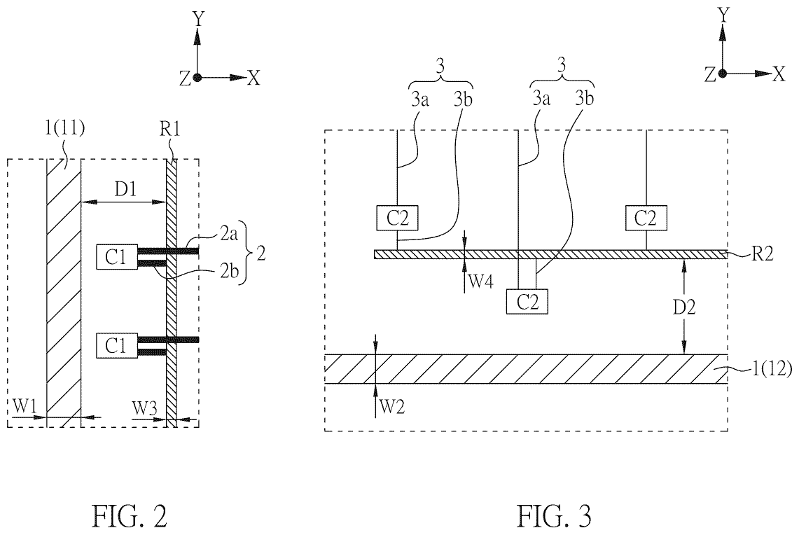

FIG. 1 is a schematic top view of an electronic device according to one embodiment of the present disclosure. FIG. 2 and FIG. 3 are partial enlarged views of FIG. 1 respectively.

In one embodiment of the present disclosure, as shown in FIG. 1, the electronic device may comprises: a substrate Sub comprising an active region AA and a peripheral region B, wherein the active region AA is adjacent to the peripheral region B, the peripheral region B may comprise a first region B1 and a second region B2, the first region B1 and the second region B2 are disposed at two adjacent sides of the active region AA; a common conductive line 1 disposed corresponding to the peripheral region B of the substrate Sub, wherein the common conductive line 1 comprises a first portion 11 disposed in the first region B1; and a scan line 2 disposed on the substrate Sub, wherein the scan line 2 may be electrically connected to a first static discharge conductive line R1 through a first electrostatic protection circuit C1 in the first region B1 of the peripheral region B, wherein the first portion 11 of the common conductive line 1 is electrically separated from the first static discharge conductive line R1.

In one embodiment of the present disclosure, as shown in FIG. 1, the electronic device may further comprise a data line 3 disposed on the substrate Sub, wherein the data line 3 may be electrically connected to a second static discharge conductive line R2 through a second electrostatic protection circuit C2 in the second region B2 of the peripheral region B. The common conductive line 1 may further comprise a second portion 12 disposed in the second region B2, wherein the second portion 12 of the common conductive line 1 is electrically separated from the second static discharge conductive line R2. Through the above design, the electronic device of the present disclosure can reduce component damage caused by electrostatic discharge and improve the reliability of the electronic device.

More specifically, as shown in FIG. 1 and FIG. 2, in the first region B1 of the peripheral region B, the scan line 2 may comprise a segment 2a and a segment 2b, the scan line may be electrically connected to the first electrostatic protection circuit C1 through the segment 2a, and electrically connected to the first static discharge conductive line R1 through the segment 2b. Thereby, the current is conducted to the first static discharge conductive line R1 through the first electrostatic protection circuit C1 to achieve the effect of electrostatic discharge, which can reduce the damage of components in the active region AA caused by electrostatic discharge. Similarly, as shown in FIG. 1 and FIG. 3, in the second region B2 of the peripheral region B, the data line 3 may comprise a segment 3a and a segment 3b, the data line 3 may be electrically connected to the second electrostatic protection circuit C2 through the segment 3a, and electrically connected to the second static discharge conductive line R2 through the segment 3b. Thereby, the current is conducted to the second static discharge conductive line R2 through the second electrostatic protection circuit C2 to achieve the effect of electrostatic discharge, which can reduce the damage of components in the active region AA caused by electrostatic discharge.

In one embodiment of the present disclosure, as shown in FIG. 2, the first electrostatic protection circuit C1 may be disposed between the common conductive line 1 and the first static discharge conductive line R1, but the present disclosure is not limited thereto. In other embodiment of the present disclosure, even not shown in the figure, the first static discharge conductive line R1 may be disposed between the common conductive line 1 and the first electrostatic protection circuit C1. Similarly, in one embodiment of the present disclosure, as shown in FIG. 3, the second static discharge conductive line R2 may be disposed between the common conductive line 1 and the second electrostatic protection circuit C2, or the second electrostatic protection circuit C2 may be disposed between the common conductive line 1 and the second static discharge conductive line R2; but the present disclosure is not limited thereto.

In one embodiment of the present disclosure, as shown in FIG. 1, the peripheral region B may further comprise a third region B3 and a fourth region B4, wherein the third region B3 may be adjacent to the first region B1 and corresponding to the second region B2, and the fourth region B4 may be adjacent to the second region B2 and corresponding to the first region B1. In one embodiment of the present disclosure, the first region B1 and the fourth region B4 of the peripheral region B may extend along a second direction Y, and the second region B2 and the third region B3 of the peripheral region B may extend along a first direction X; but the present disclosure is not limited thereto. In one embodiment of the present disclosure, the first region B1 may be connected to the second region B2 to form an L shape, and the third region B3 may be connected to the fourth region B4 to form a mirrored L shape; but the present disclosure is not limited thereto. In one embodiment of the present disclosure, the first region B1, the second region B2, the third region B3 and the fourth region B4 of the peripheral region B may be connected to form a rectangle and surround the active region AA; but the present disclosure is not limited thereto. In one embodiment of the present disclosure, in a top view Z of the substrate Sub, the first region B1 of the peripheral region B may locate, for example, at the left side of the active region AA, the second region B2 may locate, for example, at the bottom side of the active region AA, the third region B3 may locate, for example, at an upper side of the active region AA, and the fourth region B4 may locate, for example, at a right side of the active region AA; but the present disclosure is not limited thereto.

In one embodiment of the present disclosure, as shown in FIG. 1, in the fourth region B4 of the peripheral region, the scan line 2 may be electrically connected to the first static discharge conductive line R1′ through the first electrostatic protection circuit C1′. More specifically, the two ends of the scan line 2 may be electrically connected to the first static discharge conductive lines R1, R1′ through the first electrostatic protection circuits C1, C1′ respectively. In this way, the effect of electrostatic discharge can be improved. In one embodiment of the present disclosure, in the third region B3 of the peripheral region B, the data line 3 may be electrically connected to the second static discharge conductive line R2′ through the second electrostatic protection circuit C2′. More specifically, two ends of the data line 3 may be electrically connected to the second static discharge conductive lines R2, R2′ through the second electrostatic protection circuits C2, C2′ respectively. In this way, the effect of electrostatic discharge can be improved. It is worth noting that, in other embodiments of the present disclosure, one end of the scan line 2 may selectively be electrically connected to the first static discharge conductive line R1 through the first electrostatic protection circuit C1, and one end of the data line 3 may selectively be electrically connected to the second static discharge conductive line R2 through the second electrostatic protection circuit C2. This can also achieve the effect of electrostatic discharge.

In one embodiment of the present disclosure, as shown in FIG. 1, the scan line 2 may extend along the first direction X, the data line 3 may extend along the second direction Y, and the first direction X is different from the second direction Y. In one embodiment of the present disclosure, the electronic device may comprise a plurality of scan lines 2 and a plurality of data lines 3, wherein the plurality of scan lines 2 respectively extend along the first direction X, the plurality of data lines 3 respectively extend along the second direction Y, and the plurality of scan lines 2 and the plurality of data lines 3 are interlaced to form a plurality of pixel units P. For example, one pixel unit P may be formed and controlled by one data line 3 and one scan line 2. In one embodiment of the present disclosure, the first direction X may be, for example, perpendicular to the second direction Y, but the present disclosure is not limited thereto.

In one embodiment of the present disclosure, as shown in FIG. 1, the first static discharge conductive lines R1, R1′ may, for example, extend along the second direction Y, and the second static discharge conductive lines R2, R2′ may, for example, extend along the first direction X; but the present disclosure is not limited thereto. In one embodiment of the present disclosure, the first static discharge conductive lines R1, R1′ may be electrically separated from the second static discharge conductive lines R2, R2′, but the present disclosure is not limited thereto. In one embodiment of the present disclosure, even not shown in the figure, the first static discharge conductive line R1 may connect to the first static discharge conductive line R1′, and/or the second static discharge conductive line R2 may connect to the second static discharge conductive line R2′; but the present disclosure is not limited thereto. In one embodiment of the present disclosure, the static discharge conductive line may be disposed between the active region AA and the common conductive line 1, but the present disclosure is not limited thereto. In other embodiments of the present disclosure, the common conductive line 1 may be disposed between the static discharge conductive line and the active region AA. More specifically, as shown in FIG. 1, the first static discharge conductive line R1 may be disposed between the active region AA and the first portion 11 of the common conductive line 1, and the third portion 13 of the common conductive line 1 may be disposed between the second static discharge conductive line R2′ and the active region AA, but the present disclosure is not limited thereto.

In one embodiment of the present disclosure, as shown in FIG. 1, the first portion 11 of the common conductive line 1 may extend along the second direction Y, and the second portion 12 of the common conductive line 1 may extend along the first direction X, wherein the first portion 11 of the common conductive line 1 may connect to the second portion 12 to form an L shape; but the present disclosure is not limited thereto. In one embodiment of the present disclosure, as shown in FIG. 1, the common conductive line 1 may comprise a third portion 13 and a fourth portion 14, the third portion 13 is disposed in the third region B3 of the peripheral region B and extends along the first direction X, and the fourth portion 14 is disposed in the fourth region B4 of the peripheral region B and extends along the second direction Y, wherein the first portion 11, the second portion 12, the third portion 13 and the fourth portion 14 of the common conductive line 1 may connect to each other and are disposed around the active region AA; but the present disclosure is not limited thereto. The first portion 11, the second portion 12, the third portion 13 and the fourth portion 14 of the common conductive line 1 may form a rectangle, trapezoid or other suitable shape.

In one embodiment of the present disclosure, as shown in FIG. 1 and FIG. 2, in a top view Z of the substrate Sub, there is a first distance D1 between the first portion 11 of the common conductive line 1 and the first static discharge conductive line R1, and the first distance D1 may be greater than or equal to 1.5 μm and less than or equal to 12 mm. In other words, the first distance D1 may range from 1.5 μm to 12 mm (i.e. 1.5 μm≤the first distance D1≤12 mm).

In one embodiment of the present disclosure, as shown in FIG. 1 and FIG. 3, in the top view Z of the substrate Sub, there is a second distance D2 between the second portion 12 of the common conductive line 1 and the second static discharge conductive line R2, and the second distance D2 may be greater than or equal to 1.5 μm and less than or equal to 12 mm. In other words, the second distance D2 may range from 1.5 μm to 12 mm (i.e. 1.5 μm≤the second distance D2≤12 mm).

In one embodiment of the present disclosure, the first distance D1 and the second distance D2 may respectively be, for example, 1.5 μm, 5 μm, 20 μm, 50 μm, 100 μm, 300 μm, 500 μm, 1 mm, 6 mm, 12 mm or the range between any two values above; but the present disclosure is not limited thereto. When the first distance D1 and/or the second distance D2 conform the above design, the scan line 2 and/or the data line 3 can discharge static electricity respectively through the independent first static discharge conductive line R1 and/or the second static discharge conductive line R2. Therefore, the mutual interference between the scan line signal and the data line signal can be reduced. Herein, the “first distance” refers to, for example, the minimum distance between the first portion 11 of the common conductive line 1 and the first static discharge conductive line R1. Similarly, the “second distance” refers to, for example, the minimum distance between the second portion 12 of the common conductive line 1 and the second static discharge conductive line R2.

In one embodiment of the present disclosure, as shown in FIG. 1, in the first region B1 of the peripheral region B, the plurality of scan lines 2 may be electrically connected to one first static discharge conductive line R1 through a plurality of first electrostatic protection circuits C1 respectively. However, in other embodiments of the present disclosure, even not shown in the figure, in the first region B1 of the peripheral region B, the plurality of scan line 2 may respectively be electrically connected to a plurality of first static discharge conductive lines R1 through the plurality of first electrostatic protection circuits C1 to achieve the effect of electrostatic discharge. In this case, the first distance D1 between the first portion 11 of the common conductive line 1 and the first static discharge conductive line R1 may refer to, for example, the minimum distance between the first portion 11 of the common conductive line 1 and the first static discharge conductive line R1 closest to the first portion 11 of the common conductive line 1. Similarly, as shown in FIG. 1, in the second region B2 of the peripheral region B, the plurality of data lines 3 may be electrically connected to one second static discharge conductive line R2 through the plurality of second electrostatic protection circuits C2 respectively. However, in other embodiments of the present disclosure, even not shown in the figure, in the second region B2 of the peripheral region B, the plurality of data lines 3 may respectively be electrically connected to the plurality of second static discharge conductive lines R2 through the plurality of second electrostatic protection circuits C2 to achieve the effect of electrostatic discharge. In this case, the second distance D2 between the second portion 12 of the common conductive line 1 and the second static discharge conductive line R2 may refer to, for example, the minimum distance between the second portion 12 of the common conductive line 1 and the second static discharge conductive line R1 closest to the second portion 12 of the common conductive line 1.

In the present disclosure, the material of the substrate Sub may be glass, quartz, sapphire, ceramics, plastic, polycarbonate (PC), polyimide (PI), polypropylene (PP), polyethylene terephthalate (PET), polymethylmethacrylate (PMMA), other suitable materials or a combination thereof; but the present disclosure is not limited thereto. In the present disclosure, the same or different materials may be used to form the common conductive line 1, the scan line 2 and the data line 3, and suitable materials may respectively include, but are not limited to, gold, silver, copper, aluminum, titanium, chromium, nickel, molybdenum, tungsten, indium tin oxide (ITO), indium zinc oxide (IZO), indium tin zinc oxide (ITZO), indium gallium zinc oxide (IGZO) or a combination thereof. In the present disclosure, the first electrostatic protection circuits C1, C1′ and the second electrostatic protection circuits C2, C2′ may be the same as or different from each other, and may respectively comprise a diode, a transistor (for example, a thin film transistor, a capacitively coupled field effect transistor (CCFET), etc.) or a combination thereof; but the present disclosure is not limited thereto. In the present disclosure, the same of different materials may be used to form the first static discharge conductive lines R1, R1′ and the second static discharge conductive lines R2, R2′, and suitable materials may respectively include, but are not limited to gold, silver, copper, aluminum, titanium, chromium, nickel, molybdenum, tungsten, indium tin oxide (ITO), indium zinc oxide (IZO), indium tin zinc oxide (ITZO), indium gallium zinc oxide (IGZO) or a combination thereof.

In the present disclosure, the width of the static discharge conductive line may be less than or equal to the width of the common conductive line. More specifically, as shown in FIG. 2, the width W3 of the first static discharge conductive line R1 may be less than or equal to the width W1 of the first portion 11 of the common conductive line 1. Similarly, as shown in 3, the width W4 of the second static discharge conductive line R2 may be less than or equal to the width W2 of the second portion 12 of the common conductive line 1. In one embodiment of the present disclosure, the width of the common conductive line 1 (for example, the width W1 of the first portion 11 and the width W2 of the second portion 12) may be greater than 4 μm and less than or equal to 8 mm, that is 4 μm<the width W1≤8 mm and 4 μm<the width W2≤8 mm. For example, the width W1 and the width W2 may respectively range from 10 μm to 500 μm, 10 μm to 1 mm, 10 μm to 3 mm or 10 μm to 8 mm; but the present disclosure is not limited thereto. In one embodiment of the present disclosure, the width W3 of the first static discharge conductive line R1 and the width W4 of the second static discharge conductive line R2 may respectively be greater than or equal to 4 μm and less than 8 mm, that is 4 μm<the width W3≤8 mm and 4 μm≤the width W4<8 mm. For example, the width W3 and the width W4 may respectively range from 4 μm to 100 μm, 4 μm to 300 μm, 4 μm to 500 μm or 4 μm to 1 mm; but the present disclosure is not limited thereto.

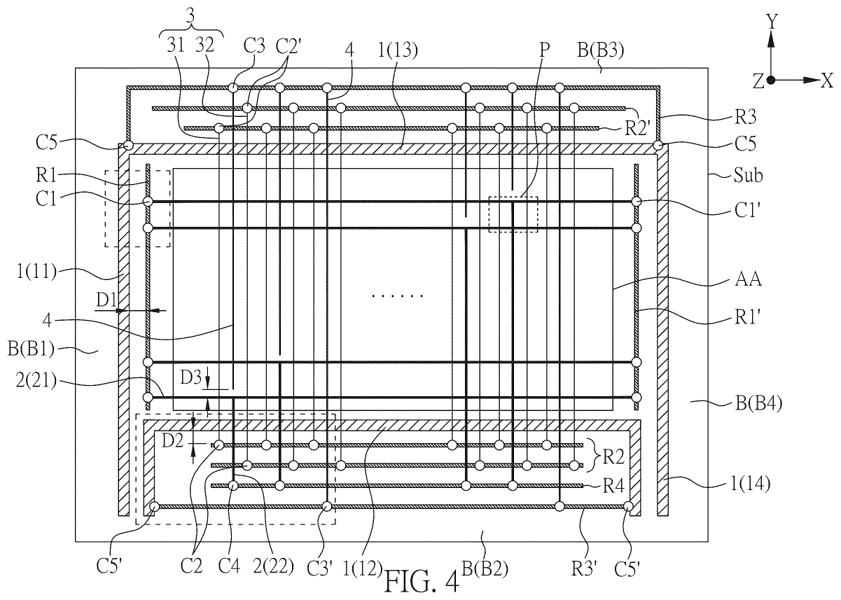

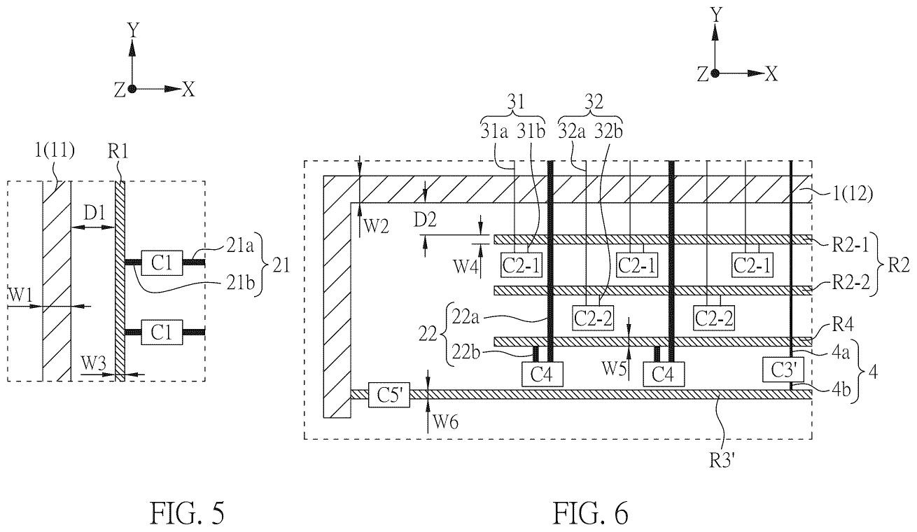

FIG. 4 is a schematic top view of an electronic device according to one embodiment of the present disclosure. FIG. 5 and FIG. 6 are partial enlarged views of FIG. 4 respectively. The electronic device shown in FIG. 4 is similar to that shown in FIG. 1, except for the following differences.

In one embodiment of the present disclosure, as shown in FIG. 4, the common conductive line 1 comprises a first portion 11, a second portion 12, a third portion 13 and a fourth portion 14. The first portion 11 is disposed in the first region B1 of the peripheral region B, the second portion 12 is disposed in the second region B2 of the peripheral region B, the third portion 13 is disposed in the third region B3 of the peripheral region B, and the fourth portion 14 is disposed in the fourth region B4 of the peripheral region B. In one embodiment of the present disclosure, as shown in FIG. 4, the first portion 11, the third portion 13 and the fourth portion 14 of the common conductive line 1 may be connected to form an inverted U shape, and the second portion 12 of the common conductive line 1 may have an inverted U shape. In one embodiment of the present disclosure, the second portion 12 of the common conductive line 1 may be separated from the first portion 11, the third portion 13 and the fourth portion 14, and electrically connected through additional suitable components such as integrated circuit (IC) or flexible printed circuit (FPC), but the present disclosure is not limited thereto. In another embodiment of the present disclosure, the first portion 11, the second portion 12, the third portion 13 and the fourth portion 14 of the common conductive line 1 may be electrically connected to each other and disposed around the active region AA; but the present disclosure is not limited thereto.

In one embodiment of the present disclosure, as shown in FIG. 4, the scan line 2 may comprise a first segment 21 and a second segment 22, the first segment 21 extends along the first direction X, the second segment 22 extends along the second direction Y, and the data line 3 extends along the second direction Y. In the top view Z of the substrate Sub, the lengths of the first segment 21 of the plurality of scan lines 2 may be the same, and the lengths of the second segment 22 of the plurality of scan lines 2 may be different. In the first region B1 of the peripheral region B, the first segment 21 of the scan line 2 may be electrically connected to the first static discharge conductive line R1 through the first electrostatic protection circuit C1. In the second region B2 of the peripheral region B, the second segment 22 of the scan line 2 may be electrically connected to a fourth static discharge conductive line R4 through a fourth electrostatic protection circuit C4. More specifically, as shown in FIG. 5, the first segment 21 of the scan line 2 may be electrically connected to the first electrostatic protection circuit C1 through a segment 21a, and electrically connected to the first static discharge conductive line R1 through a segment 21b. Therefore, the current may be conduct to the first static discharge conductive line R1 through the first electrostatic protection circuit C1 to achieve the effect of electrostatic discharge. In addition, as shown in FIG. 6, the second segment 22 of the scan line 2 may be electrically connected to the fourth electrostatic protection circuit C4 through the segment 22a, and electrically connected to the fourth static discharge conductive line R4 through the segment 22b. Thus, the current may be conduct to the fourth static discharge conductive line R4 through the fourth electrostatic protection circuit C4 to achieve the effect of electrostatic discharge. In one embodiment of the present disclosure, the first segment 21 and the second segment 22 of the scan line 2 may be manufactured by different metal layers, so the first segment 21 of the scan line 2 may be electrically connected to the second segment 22 of the scan line 2 through a conductive via; but the present disclosure is not limited thereto. In one embodiment of the present disclosure, the first segment 21 and the second segment 22 of the scan line 2 may be manufactured by the same metal layer.

In one embodiment of the present disclosure, as shown in FIG. 4, in the second region B2 of the peripheral region B, the plurality of data lines 3 may be electrically connected to the plurality of second static discharge conductive lines R2 through the plurality of second electrostatic protection circuits C2 respectively. More specifically, as shown in FIG. 4 and FIG. 6, the plurality of data lines 3 may comprise a first data line 31 and a second data line 32, the first data line 31 comprises a segment 31a and a segment 31b, and the second data line 32 comprises a segment 32a and a segment 32b. The first data line 31 may be electrically connected to the second electrostatic protection circuit C2-1 through the segment 31a, and electrically connected to the second static discharge conductive line R2-1 through the segment 31b. The second data line 32 may be electrically connected to the second electrostatic protection circuit C2-2 through the segment 32a, and electrically connected to the second static discharge conductive line R2-2 through the segment 32b. Therefore, the current may be conducted to the second static discharge conductive lines R2-1, R2-2 through the second electrostatic protection circuits C2-1, C2-2 respectively to achieve the effect of electrostatic discharge. In one embodiment of the present disclosure, the plurality of data lines 3 may be electrically connected to one second static discharge conductive line R2 through a plurality of second electrostatic protection circuits C2 respectively. For example, the first data line 31 and the second data line 32 may be electrically connected to the same second static discharge conductive line R2-1 through the second electrostatic protection circuit C2-1 and the second electrostatic protection circuit C2-2 respectively.

In one embodiment of the present disclosure, as shown in FIG. 5, the first static discharge conductive line R1 may be disposed between the common conductive line 1 and the first electrostatic protection circuit C1, but the present disclosure is not limited thereto. In other embodiments of the present disclosure, even not shown in the figure, the first electrostatic protection circuit C1 may be disposed between the common conductive line 1 and the first static discharge conductive line R1. Similarly, in one embodiment of the present disclosure, as shown in FIG. 6, the second static discharge conductive lines R2-1, R2-2 may be respectively disposed between the common conductive line 1 and the second electrostatic protection circuits C2-1, C2-2 electrically connected thereto, but the present disclosure is not limited thereto. In other embodiments of the present disclosure, even not shown in the figure, the second electrostatic protection circuits C2-1, C2-2 may be respectively disposed between the common conductive line 1 and the second static discharge conductive lines R2-1, R2-2 electrically connected thereto.

In one embodiment of the present disclosure, as shown in FIG. 4 and FIG. 5, in the top view Z of the substrate Sub, there is a first distance D1 between the first portion 11 of the common conductive line 1 and the first static discharge conductive line R1, and the first distance D1 may be greater than or equal to 1.5 μm and less than or equal to 12 mm (i.e. 1.5 μm≤the first distance D1≤12 mm). In one embodiment of the present disclosure, as shown in FIG. 4 and FIG. 6, in the top view Z of the substrate Sub, there is a second distance D2 between the second portion 12 of the common conductive line 1 and the second static discharge conductive line R2-1, and the second distance D2 may be greater than or equal to 1.5 μm and less than or equal to 12 mm (i.e. 1.5 μm≤the second distance D2≤12 mm). When the first distance D1 and/or second distance D2 conform the above design, the scan line 2 and/or the data line 3 may discharge static electricity through independent first static discharge conductive line R1 and/or second static discharge conductive line R2-1 respectively, and therefore the mutual interference between scan line signals and data line signals can be reduced.

In one embodiment of the present disclosure, as shown in FIG. 4, the electronic device may further comprise a conductive line 4 disposed on the substrate Sub, wherein the conductive line 4 extends along the second direction Y and is electrically separated from the scan line 2. In the top view Z of the substrate Sub, the conductive line 4 may be disposed between the first data line 31 and the second data line 32. In one embodiment of the present disclosure, the conductive line 4 may be opposite to the second segment 22 of the scan line 2. In the top view Z of the substrate Sub, there is a third distance D3 between the conductive line 4 and the second segment 22 of the scan line 2, and the third distance D3 may be greater than or equal to 2 μm and less than or equal to 100 μm. In other words, the third distance D3 may range from 2 μm to 100 μm (i.e. 2 μm≤the third distance D3≤100 μm). Furthermore, the third distance D3 may be 2 μm, 5 μm, 10 μm, 20 μm, 35 μm, 50 μm, 70 μm, 90 μm, 100 μm or any numerical range; but the present disclosure is not limited thereto. When the design of the conductive line 4 meets the above restrictions, the taste of the electronic device can be improved. For example, when the electronic device is a display device, the visual performance thereof can be improved. Herein, “the conductive line is opposite to the second segment of the scan line” may refer to, for example, the conductive line 4 may be overlapped with an extension line of the second segment 22 in the top view Z of the substrate Sub.

In one embodiment of the present disclosure, as shown in FIG. 4, the first segments 21 of the plurality of scan lines 2 extend along the first direction X, the plurality of data line 3 (comprising the first data line 31 and the data line 32) extend along the second direction Y, and the first segment 21 of the plurality of scan lines 2 and the plurality of data lines 3 are interlaced to form a plurality of pixel units P. For example, one pixel unit P may be formed by the first data line 31, the second data line 32 and the first segment 21 of one scan line 2, and the active region AA may be formed by a plurality of pixel units P repeatedly arranged. One pixel unit P may be controlled by the first segment 21 of one scan line 2 and one of the data line 31 and the data line 32. For example, even not shown in the figure, in the second direction Y, odd numbered pixel unit P is controlled by the first segment 21 of one scan line 2 and one of the data line 31 and the data line 32, and even numbered pixel unit P is controlled by the first segment 21 of one scan line 2 and the other one of the data line 31 and the data line 32; but the present disclosure is not limited thereto. Thus, in one embodiment of the present disclosure, as shown in FIG. 4, in the top view Z of the substrate Sub, the conductive line 4 may be overlapped with the pixel unit P, but the present disclosure is not limited thereto. In another embodiment of the present disclosure, the electronic device may not comprise the second data line 32 shown in FIG. 4; therefore, the pixel unit of this case (not shown in the figure) may be formed and controlled by the first data line 31 and the first segment 21 of one scan line 2, and the active region AA may be formed by a plurality of above pixel units (not shown in the figure) repeatedly arranged.

In one embodiment of the present disclosure, as shown in FIG. 4, in the third region B3 of the peripheral region B, the conductive line 4 may be electrically connected to a third static discharge conductive line R3 through a third electrostatic protection circuit C3, so the current may be conducted to the third static discharge conductive line R3 through the third electrostatic protection circuit C3 to achieve the effect of electrostatic discharge. In one embodiment of the present disclosure, as shown in FIG. 4, in the second region B2 of the peripheral region B, the conductive line 4 may be electrically connected to a third static discharge conductive line R3′ through a third electrostatic protection circuit C3′. More specifically, as shown in FIG. 6, the conductive line 4 may be electrically connected to the third electrostatic protection circuit C3′ through a segment 4a, and electrically connected to the third static discharge conductive line R3′ through a segment 4b. Thus, the current can be conducted to the third static discharge conductive line R3′ through the third electrostatic protection circuit C3′ to achieve the effect of electrostatic discharge. In one embodiment of the present disclosure, as shown in FIG. 6, the third electrostatic protection circuit C3′ may be disposed between the common conductive line 1 and the third static discharge conductive line R3′, but the present disclosure is not limited thereto. In other embodiments of the present disclosure, even not shown in the figure, the third static discharge conductive line R3′ may be disposed between the common conductive line 1 and the third electrostatic protection circuit C3′. In one embodiment of the present disclosure, as shown in FIG. 4, the third static discharge conductive line R3 may be electrically connected to the common conductive line 1 through a fifth electrostatic protection circuit C5, but the present disclosure is not limited thereto. In one embodiment of the present disclosure, as shown in FIG. 4 and FIG. 6, the third static discharge conductive line R3′ may be electrically connected to the common conductive line 1 through a fifth electrostatic protection circuit C5′; but the present disclosure is not limited thereto.

In the present disclosure, the materials of the substrate Sub, the common conductive line 1, the scan line 2 and the data line 3 may be similar to those described above and are not repeated here. In the present disclosure, the conductive line 4 and the second segment 22 of the scan line 2 may be disposed on the same layer or different layers. The conductive line 4 may be prepared by the same or different materials of the scan line 2, and suitable materials include, but are not limited to gold, silver, copper, aluminum, titanium, chromium, nickel, molybdenum, tungsten, indium tin oxide (ITO), indium zinc oxide (IZO), indium tin zinc oxide (ITZO), indium gallium zinc oxide (IGZO) or a combination thereof. In the present disclosure, the third electrostatic protection circuits C3, C3′, the fourth electrostatic protection circuit C4 and the fifth electrostatic protection circuits C5, C5′ may be the same or different, and may respectively comprise a diode, a transistor (for example, a thin film transistor or a capacitively coupled field effect transistor (CCFET)) or a combination thereof, but the present disclosure is not limited thereto. In the present disclosure, the same or different materials may be used to form the third static discharge conductive lines R3, R3′ and the fourth static discharge conductive lines R4, and suitable materials respectively include, but are not limited to gold, silver, copper, aluminum, titanium, chromium, nickel, molybdenum, tungsten, indium tin oxide (ITO), indium zinc oxide (IZO), indium tin zinc oxide (ITZO), indium gallium zinc oxide (IGZO) or a combination thereof.

In the present disclosure, the width of the static discharge conductive line may be less than or equal to the width of the common conductive line. More specifically, as shown in FIG. 5, the width W3 of the first static discharge conductive line R1 may be less than or equal to the width W1 of the first portion 11 of the common conductive line 1. Similarly, as shown in FIG. 4 and FIG. 6, the widths W4 of the second static discharge conductive lines R2-1, R2-2, the width W5 of the fourth static discharge conductive line R4 and the width W6 of the third static discharge conductive line R3′ may be less than or equal to the width W2 of the second portion 12 of the common conductive line 1. In one embodiment of the present disclosure, the width of the common conductive line 1 (for example, the width W1 of the first portion 11 and the width W2 of the second portion 12) may be greater than 4 μm and less than or equal to 8 mm; and that is 4 μm<the width W1≤8 mm and 4 μm<the width W2≤8 mm. For example, the width W1 and the width W2 may respectively range from 10 μm to 500 μm, 10 μm to 1 mm, 10 μm to 3 mm or 10 μm to 8 mm, but the present disclosure is not limited thereto. In one embodiment of the present disclosure, the width W3 of the first static discharge conductive line R1, the widths W4 of the second static discharge conductive lines R2-1, R2-2, the width W5 of the fourth static discharge conductive line R4 and the width W6 of the third static discharge conductive line R3′ may be respectively greater than or equal to 4 μm and less than 8 mm, that is 4 μm≤the width (for example, W3, W4, W5 and W6)<8 mm. For example, the width W3, the width W4, the width W5 and the width W6 may respectively range from 4 μm to 100 μm, 4 μm to 300 μm, 4 μm to 500 μm or 4 μm to 1 mm; but the present disclosure is not limited thereto.

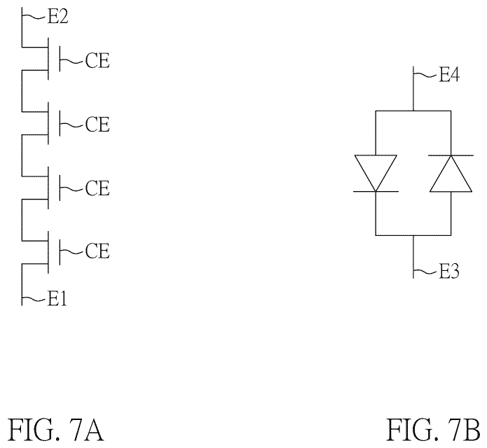

FIG. 7A and FIG. 7B are respectively schematic diagrams of an electrostatic protection circuit according to one embodiment of the present disclosure.

In one embodiment of the present disclosure, as shown in FIG. 7A, the electrostatic protection circuit may comprise a plurality of transistors connected in series, and the plurality of transistors connected in series are used to discharge the static charge generated by the electronic device to avoid damage to components in the electronic devices caused by the accumulation of static charges. Herein, “the electrostatic protection circuit” includes any of the first electrostatic protection circuits C1, C1′, the second electrostatic protection circuits C2, C2′, C2-1, C2-2, the third electrostatic protection circuits C3, C3′, the fourth electrostatic protection circuit C4 and the fifth electrostatic protection circuits C5, C5′ mentioned above, and are not described again. In the present embodiment, the electrostatic protection circuit shown in FIG. 7A comprise 4 transistors connected in series as an example, but the present disclosure is not limited thereto. In other embodiments of the present disclosure, the number of the transistors connected in series may be adjusted according to the needs, and the number of the transistors in each electrostatic protection circuit may be the same or different.

In one embodiment of the present disclosure, as shown in FIG. 7A, the control terminals CE of the plurality of transistors are floating, and one end E1 of the plurality transistors connected in series may be electrically connected to the corresponding electrostatic discharge line, and the other end E2 may be electrically connected to the corresponding connection line (such as the scan line 2, the data line 3 or the conductive line 4). More specifically, taking the first electrostatic protection circuit C1 as an example, when the first electrostatic protection circuit C1 has the structure shown in FIG. 7A, as shown in FIG. 1 and FIG. 7A, one end E1 of the plurality of transistors connected in series may be electrically connected to the first static discharge conductive line R1, and the other end E2 may be electrically connected to the scan line 2; but the present disclosure is not limited thereto.

In another embodiment of the present disclosure, as shown in FIG. 7B, the electrostatic protection circuit may comprise a back to back diode, wherein the back to back diode has a good electrostatic discharge effect, which can prevent the accumulation of static charges from causing damage to components in the electronic device. Herein, “the electrostatic protection circuit” includes any of the first electrostatic protection circuits C1, C1′, the second electrostatic protection circuits C2, C2′, C2-1 and C2-2, the third electrostatic protection circuits C3, C3′, the fourth electrostatic protection circuit C4 and the fifth electrostatic protection circuits C5, C5′ mentioned above, and are not described again. In the present embodiment, the electrostatic protection circuit with two back to back diodes shown in FIG. 7B is used as an example, but the present disclosure is not limited thereto. In other embodiments of the present disclosure, the number of the diodes may be adjusted according to the needs, and the number of the diodes in each electrostatic protection circuit may be the same or different.

In one embodiment of the present disclosure, as shown in FIG. 7B, one end E3 of the back to back diode may be electrically connected to the corresponding electrostatic discharge line, and the other end E4 may be electrically connected to the corresponding connection line (such as the scan line 2, the data line 3 or the conductive line 4). More specifically, taking the first electrostatic protection circuit C1 as an example, when the first electrostatic protection circuit C1 has the structure shown in FIG. 7B, as shown in FIG. 1 and FIG. 7B, one end E3 of the back to back diode may be electrically connected to the first static discharge conductive line R1, and the other end E4 may be electrically connected to the scan line 2; but the present disclosure is not limited thereto.

In addition, even not shown in the figure, in one embodiment of the present disclosure, the electrostatic protection circuit may comprise the structures shown in FIG. 7A and FIG. 7B. More specifically, for example, one end E1 of the transistors connected in series shown in FIG. 7A may be electrically connected to the corresponding connection line (for example, the first static discharge conductive line R1 shown in FIG. 1), the other end E2 may be electrically connected to one end E3 of the back to back diode shown in FIG. 7B, and the other end E4 of the back to back diode shown in FIG. 7B may be electrically connected to the corresponding connection line (for example, the scan line 2 shown in FIG. 1); but the present disclosure is not limited thereto. In the present disclosure, by using the electrostatic protection circuits shown in FIG. 7A and FIG. 7B, the effect of electrostatic discharge can be achieved.

The above specific embodiments are to be construed as illustrative only and not in any way limiting of the remainder of the present disclosure.

Although the present disclosure has been explained in relation to its embodiment, it is to be understood that many other possible modifications and variations can be made without departing from the spirit and scope of the disclosure as hereinafter claimed.

1. An electronic device, comprising:
a substrate comprising an active region and a peripheral region;
a common conductive line disposed corresponding to the peripheral region of the substrate; and
a scan line disposed on the substrate, wherein the scan line is electrically connected to a first static discharge conductive line through a first electrostatic protection circuit in the peripheral region,
wherein the common conductive line is electrically separated from the first static discharge conductive line; wherein in a top view of the substrate, there is a first distance between the common conductive line and the first static discharge conductive line, and the first distance is greater than or equal to 1.5 μm and less than or equal to 12 mm.

2. The electronic device of claim 1, wherein the scan line is electrically connected to the first electrostatic protection circuit through a segment of the scan line, and electrically connected to the first static discharge conductive line through another segment of the scan line.

3. The electronic device of claim 1, further comprising a data line disposed on the substrate, wherein the data line is electrically connected to a second static discharge conductive line through a second electrostatic protection circuit in the peripheral region, wherein the common conductive line is electrically separated from the second static discharge conductive line.

4. The electronic device of claim 3, wherein the first static discharge conductive line is electrically separated from the second static discharge conductive line.

5. The electronic device of claim 3, wherein the scan line comprises a first segment and a second segment, the first segment extends along a first direction, the second segment extends along a second direction, the first direction is different from the second direction, and the data line extends along the second direction.

6. The electronic device of claim 5, further comprising a conductive line disposed on the substrate, wherein the conductive line extends along the second direction, and is overlapped with an extension line of the second segment and electrically separated from the scan line.

7. The electronic device of claim 6, wherein in the top view of the substrate, there is a third distance between the conductive line and the scan line, and the third distance is greater than or equal to 2 μm and less than or equal to 100 μm.

8. The electronic device of claim 6, wherein the conductive line is electrically connected to a third static discharge conductive line through a third electrostatic protection circuit in the peripheral region.

9. The electronic device of claim 8, wherein the third static discharge conductive line is electrically connected to the common conductive line.

10. The electronic device of claim 5, further comprising a fourth static discharge conductive line disposed in the peripheral region, wherein the first segment of the scan line is electrically connected to the first static discharge conductive line, and the second segment of the scan line is electrically connected to the fourth static discharge conductive line.

11. The electronic device of claim 1, wherein a width of the first static discharge conductive line is less than or equal to a width of a first portion of the common conductive line.

12. The electronic device of claim 1, wherein the peripheral region comprises a first region and a second region, the first region and the second region are disposed at two adjacent sides of the active region, and a first portion of the common conductive line is disposed in the first region.

13. The electronic device of claim 12, wherein the first portion of the common conductive line is electrically separated from the first static discharge conductive line.

14. The electronic device of claim 12, further comprising a data line disposed on the substrate, wherein the data line is electrically connected to a second static discharge conductive line through a second electrostatic protection circuit in the peripheral region, wherein a second portion of the common conductive line is electrically separated from the second static discharge conductive line.

15. The electronic device of claim 14, wherein in the top view of the substrate, there is a second distance between the second portion of the common conductive line and the second static discharge conductive line, and the second distance is greater than or equal to 1.5 μm and less than or equal to 12 mm

16. The electronic device of claim 12, further comprising a conductive line disposed on the substrate, wherein the peripheral region further comprises a third region adjacent to the first region and corresponding to the second region, and the conductive line is electrically connected to a third static discharge conductive line through a third electrostatic protection circuit in the third region of the peripheral region.

17. The electronic device of claim 1, wherein the first electrostatic protection circuit comprises a diode.

18. The electronic device of claim 1, wherein the first electrostatic protection circuit comprises a transistor.

19. The electronic device of claim 1, wherein a width of the common conductive line is greater than 4 μm and less than or equal to 8 mm.

20. The electronic device of claim 1, wherein a width of the first static discharge conductive line is greater than or equal to 4 μm and less than 8 mm.
